(19) United States
(12) Patent Application Publication
(10) Pub. No.: US 2013/0068291 A1
(43) Pub. Date: Mar. 21, 2013

(54) DYE-SENSITIZED SOLAR CELLS

(71) Applicants: Adélio Miguel Magalhães Mendes, Porto (PT); Luísa Manuela Madureira Andrade, Ermeside (PT); Ruí Alberto Teixeira Cruz, Canelas (PT)

(72) Inventors: Adélio Miguel Magalhães Mendes, Porto (PT); Luísa Manuela Madureira Andrade, Ermeside (PT); Ruí Alberto Teixeira Cruz, Canelas (PT)

(21) Appl. No.: 13/583,500

(22) PCT Filed: Mar. 7, 2011
(86) PCT No.: PCT/IB2011/050945

§ 371 Date: Sep. 7, 2012

(30) Foreign Application Priority Data
Mar. 9, 2010 (PT) 104996

(51) Int. Cl. H01L 31/0216

(52) U.S. Cl. 136/256

(57) ABSTRACT

The present invention discloses an innovative way to improve the conversion efficiency of solar energy into electric energy of dye-sensitized solar cells. The solar cells of the present invention present a film obtained by painting a light reflective coating (6) onto the outer surface of the counter-electrode (4). A commercial paint of any color can be used. The solar cells of the present invention usually comprise two glass sheets coated with a transparent and electrically conductive layer (1) and (5), a photoelectrode (2), an electrolyte (3), a counter-electrode (4) and a light reflective paint film applied onto the outer surface of the counter-electrode and obtained by painting a light reflective coating (6). After applying this reflective film (6) onto the outer surface of the counter-electrode (4) a series of remarkable results were obtained; coating with a white paint as a reflective film significantly increased the solar cell efficiency up to 30%.

### TECHNICAL FIELD

The present invention describes a new kind of dye-sensitized solar cell coated with a paint film applied in the external part of the counter-electrode of the cell and capable of reflecting the light that has passed through the cell.

These cells are photoelectrochemical cells able to convert solar energy into electric current.

### BACKGROUND ART

Dye-sensitized solar cells (DSCs) are photoelectrochemical cells able to convert solar energy into electric current.^{[1]} In 1980 Skotheim^{[2]} described a relatively low cost solar cell which he called dye-sensitized Schottky barrier solar cell. However, it was only in 1991, with the outstanding work developed by Brian O'Regan and Michael Grätzel that the DSCs showed their true potential in electricity generation, showing as main advantages their low cost and relatively easy manufacturing process.^{[1]} Brian O'Regan and Michael Grätzel used a TiO₂ nanoparticle film with high surface area. This structure enabled an increase in the amount of adsorbed dye and consequently in the number of adsorbed photons, thus a photoelectrical conversion efficiency of more than 7% have been achieved. The operation principle of this kind of photoeletrochemical cells and manufacturing process thereof is reported by

Michael Grätzel and his co-authors in U.S. Pat. No. 4,927,721 and U.S. Pat. No. 5,084,365.^{[3; 4]}

A typical DSC consists of a mesoporous and nanostructured semiconductive oxide film, usually titanium dioxide, which nanoparticles are deposited onto a glass substrate coated with a transparent and conductive SnO₂:F film (TCO—Transparent Coating Oxide). Adsorbed onto the surface of the nanocrystalline film is a monolayer of dye, which is responsible for the absorption of solar radiation—photoelectrode. As a result of the dye's photoexcitation, electrons from the valence band are injected into the titanium dioxide's conduction band. These electrons then diffuse through the TiO₂ film and are collected at the TCO where they are led toward the cell's external circuit. The oxidized dye is subsequently regenerated by the electrolyte that fills the space between the photoelectrode and the counter-electrode. Typically the electrolyte consists of a solution of an ionic liquid solvent containing a triiodide/iodide redox system. The triiodide ion transfers an electron to the dye, regenerating it, thus yielding iodide ions. In turn, the iodide ion is itself regenerated at the platinum counter-electrode through triiodide reduction with electrons flowing through the cell's external circuit. Therefore, DSCs enable electricity generation from sunlight without any lasting chemical transformation.

So far DSCs are capable of converting sunlight into electric current with a reported maximum efficiency of just over 11%.^{[5]} Thus, and despite the aforementioned advantages of this type of solar cells, one must take the low values of solar energy to electric current conversion efficiency into consideration. One solution to overcome this limitation is to increase the amount of absorbed incident light. Owing to that, different efforts have been undertaken to develop more efficient dyes, nanocrystalline electrodes, electrolytes and counter-electrodes.^{[1]} On the other hand, light absorption has also been enhanced by the use of structures that are made of large TiO₂ particles (˜400 nm diameter), which are able to scatter part of the incident light that otherwise would be lost due to the photoelectrode transparency. Additionally, the tandem cell embodiment proposed by Kubo et al.^{[6]}, wherein a mixture of N719 and back dyes is used, yielded an increase in the spectral response and photocurrent, and consequently in the overall system's efficiency.

Another feature that must be taken into consideration is the DSCs electrode transparency. Although transparent electrodes are very advantageous regarding the use of DSCs in outer windows of the buildings, it has the disadvantage of loosing part of the incident radiation since it cannot be fully absorbed when passing through the photoelectrode as the light is sharply transmitted. Therefore, Nazeeruddin et al.^{[7]} developed a counter-electrode that is able to reflect part of the transmitted light that passes through the transparent semiconductor. This counter-electrode consists of a TCO coated conductive glass where a 2 μm-thick platinum film is deposited by sputtering. Nevertheless, the amount of platinum needed in this deposition method is significantly higher than the amount needed in the conventional method, therefore increasing production costs due to platinum's high-cost as raw material. Moreover, the commonly used deposition method of platinum by thermal decomposition, which cost is significantly lower, cannot be used for this purpose as it originates a transparent film. Other authors have tried to simultaneously combine the increase of the counter-electrode's catalytic activity with the light reflection properties thereof. As a matter of fact, the preparation of counter-electrodes containing Ni-P and titanium based structures, both in association with platinum, showed an increase in light reflection, mainly in the red part of the spectrum.^{[8]} The same concept was used by Ji et al.^{[9]}, but his films were made of aluminum and platinum structures. Despite being easy to prepare, these films yielded significant improvements in DSCs' efficiencies due to their low electrical resistance and high light reflectivity. However, these films seem to cause accelerated aging on DSCs. In 2006, Liu et al.^{[10]} described the use of a reflective silver film applied onto the outer surface of the counter-electrode. This way, the part of incident light passing through the photoelectrode is reflected by the silver film. A significant increase in light absorption was observed and consequently in the solar energy to electric current conversion efficiency.^{[10]} Though the application method is relatively easy, one should note the high-cost of the silver film and its susceptibility to outdoor degradation.

### SUMMARY

One of the objects of the present invention is the description of a dye-sensitized solar cell comprising a light reflective film (6) on the outer surface of the counter-electrode (4), wherein the mentioned film is obtained by applying a paint coat.

In known dye-sensitized solar cells, part of the incident light radiation that passes through the cell is lost without producing electric current.

According to the present invention, light radiation that is reflected by the light reflective film (6) on the outer surface of the counter-electrode (4) is returned to the photoelectrode (2), allowing for a greater fraction of incident light to be absorbed; the paint coating surprisingly maximizes the reflected light.

Upon application of the proposed reflective film, surprising results were obtained namely when using high reflectance paints of any color; the application of a layer of white paint as reflective film allows a significant increase in the efficiency of these cells up to 30%. The best results were achieved with CINAQUA® white paint.

The present invention further describes a dye-sensitized solar cell consisting of:
two layers of impervious material to the electrolyte and capable of protecting the cell (1) and (5), having their inner surface coated with a transparent and electrically conductive layer; preferably, the two layers should be made of glass or PET—polyethylene terephthalate;
a photoelectrode (2), preferably dye-sensitized nanoparticulated titanium dioxide;
an electrolyte (3), preferably the triiodide/iodide redox system;
a counter-electrode (4), preferably a platinum thin layer, preferably among 5 nm<thickness<500 nm or nanostructured carbon particles either or not doped with platinum;
wherein the mentioned light reflective layer (6) is applied onto the outer surface of the counter-electrode (4);

It is also an objective of the present invention the application onto the aforementioned dye-sensitized solar cells of a light reflective paint coating, preferably a high-reflectance paint, preferably with reflectance superior to 80%, preferably 81%, 82%, 83%, 84%, 85%, 86%, 87%, 88%, 89%, 90%, 91%, 92%, 93%, 94%, 95%, 96%, 97%, 98%, 99; more preferably a white color paint, such as CINAQUA®.

### DESCRIPTION OF DRAWINGS

For an easier understanding of the present invention, a Figure is herewith attached representing a preferred embodiment of the invention which, however, does not intend to limit the scope thereof.

FIG. 1 schematic view of a dye-sensitized solar cell. The reflective film (6) applied by paint coating of the outer surface of the counter-electrode (4) allows a significant increase in the efficiency of these cells.

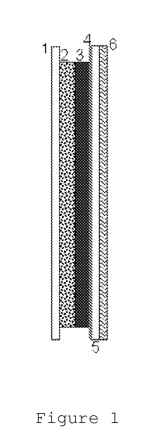

In particular, the said figure shows:

Wherein (1) represents the glass sheet coated with a conductive film—TCO acting as support of the DSC photoelectrode;

Wherein (2) represents the photoelectrode, a dye-sensitized semiconductor—photoanode;

Wherein (3) represents the electrolyte that fills the space between the photoelectrode and the counter-electrode;

Wherein (4) represents the counter-electrode—platinum catalyst;

Wherein (5) represents the glass sheet coated with a conductive film (TCO) acting as support of the DSC counter-electrode;

Wherein (6) represents the light reflective film applied onto the outer surface of the glass sheet supporting the counter-electrode.

### DETAILED DESCRIPTION

The present invention proposes a dye-sensitized solar cell (DSC) containing a high absorption rate of incident radiation and hence high efficiency, without a significant increase in the manufacturing costs. For such, the present invention describes the use of a light reflective film (6), preferably using a low cost material, applied by painting the outer surface of the counter-electrode (4). Bearing in mind that part of the incident radiation that passes through the photoelectrode (2) is lost without being absorbed, the reflective layer causes the return thereof back into the photoanode, providing it with a second opportunity to absorb the said radiation. The present patent describes the use of a paint, preferably white and suitable for outdoor applications, as reflective layer applied onto the outer surface of the counter-electrode; the reflective layer of paint also acts as protection and should have high light reflectance. However, a paint film of a color other than white can be used for aesthetic purposes, although providing lower light reflectance yield.

The application of the reflective film onto the outer surface of the counter-electrode (4) has the additional advantage of aiding in minimizing the degradation of the counter-electrode (4) support.

The present invention describes a dye-sensitized solar cell with an increased efficiency regarding solar energy into electrical energy conversion.

Solar cells of the present invention comprise a film obtained by painting a light reflective coating (6) onto the outer surface of the counter-electrode (4), the coating is a conventional paint of any color.

The cells object of the present invention may also consist of two glass sheets coated with a transparent and electrically conductive layer(1) and (5), a photoelectrode (2), an electrolyte (3), a counter-electrode (4) and a non-reflective film applied onto the outer surface of the counter-electrode (4); this film is obtained by painting a light reflective coating (6).

Presently, a significant portion of incident solar energy is lost without having the possibility of being converted into electric current. The present invention describes a simple way to minimize such losses by adding reflective film (6) onto the counter-electrode (4). Upon application of this reflective film (6) surprising results were obtained; the application by painting a white paint layer as reflective film (6) allows a significant increase in the efficiency of these cells up to 30%.

Therefore, the use of the paint film herein disclosed finds suitable application in situations wherein the semi-transparency characteristic of dye-sensitized cells is not mandatory, such as in facades and rooftops, among others. In the case of facades, the application of reflective films of different colors can provide an aesthetic effect while simultaneously boosting efficiency, at a very low cost. It has been found that the use of a white reflective paint allows a significant increase of the DSC efficiency up to 30%.

In order to better understand the present invention, a preferable embodiment of the invention is hereinafter described which, however, is not intended to limit the scope of the invention.

### EXAMPLE 1

This example illustrates the application of Vinil Matt® paint by CIN, SA as a reflective film. Two-coats were applied onto the outer surface of the counter-electrode, following the instructions of the paint manufacturer. The dye-sensitized cell consists of two glass sheets coated, on one side with a transparent and electrical conductive layer. Onto one of the glass sheets and on top of the conductive layer, a 7 μm-thick layer of 20 nm diameter TiO₂ particles was applied, on top of which a second 5 μm-thick layer of 400 nm diameter TiO₂ particles was later applied. After sintering, the dye N719 was adsorbed on the surface of the semiconductor. The photoelectrode was sealed with the counter-electrode using a transparent ring of Surlyn (by DuPont) with a thickness of 25 μm. The counter-electrode (4) was prepared using the second glass sheet onto which a platinum solution film was deposited. Subsequent to platinum deposition, the counter-electrode remained transparent since the platinum film was very thin. The space between both electrodes was filled with an electrolyte (3) consisting of iodine (0.1 M) and N-methylbenzimidazol (0.5 M) in a mixture of BMII; PMI-TFSI; γ-BL (2;3;1) vol/vol.

The individual DSC, without the reflective film, yielded a photocurrent of 13.7 mA·cm⁻² and an efficiency of 6.3%, whereas, upon the coating of the reflective film of paint, it yielded a photocurrent of 16.9 mA·cm⁻² and an efficiency of 7.8%. These values were measured for a radiant power of 1000 W m⁻² and an air mass of AM 1.5.

### REFERENCES

B. O'Regan, and M. Grätzel, A Low-Cost, High-Efficiency Solar-Cell Based on Dye-Sensitized Colloidal TiO₂ Films. Nature 353 (1991) 737-740.

T. Skotheim, Dye-sensitized Solar Cells, U.S. Pat. No. 4,190,950, 1980.

M. Grätzel, and P. Liska, Photo-Electrochemical Cell, U.S. Pat. No. 4,927,721, 1990.

M. Grätzel, and P. Liska, Photo-Electrochemical cell and process of making same, U.S. Pat. No. 5,084,365, 1992.

M. Grätzel, Molecular photovoltaics that mimic photosynthesis. Pure and Applied Chemistry 73 (2001) 459-467.

W. Kubo, A. Sakamoto, T. Kitamura, Y. Wada, and S. Yanagida, Dye-sensitized solar cells: improvement of spectral response by tandem structure. Journal of Photochemistry and Photobiology A: Chemistry 164 (2004) 33-39.

M. Nazeeruddin, A. Kay, I. Rodicio, R. Humphry-Baker, E. Mueller, P. Liska, N. Vlachopoulos, and M. Grätzel, Conversion of light to electricity by cis-X2bis(2,2′-bipyridyl-4,4′-dicarboxylate)ruthenium(II) charge-transfer sensitizers (X═Cl—, Br—, I—, CN—, and SCN—) on nanocrystalline titanium dioxide electrodes. J. Am. Chem. Soc. 115 (1993) 6382-6390.

G. Wang, and Y. Lin, Novel counter electrodes based on NiP-plated glass and Ti plate substrate for dye-sensitized solar cells. Journal of Materials Science 42 (2007) 5281-5285.

W. Ji, N. Cai, Y. Zhao, X. Zhang, J. Sun, C. Wei, C. Yuan, Y. Li, Y. Su, and S. Xiong, A new type counter electrode for dye-sensitized solar cells. Science in China Series E: Technological Sciences 52 (2009) 1923-1927.

Y. Liu, H. Shen, X. Huang, and Y. Deng, A new improved structure of dye-sensitized solar cells with reflection film. Chinese Science Bulletin 51 (2006) 369-373.

1. A dye-sensitized solar cell comprising a light reflective film (6) deposited onto the outer surface of the counter-electrode (4) wherein said film is obtained by painting a coating and said reflective coating is a high reflectance paint having a reflectance above 80%.

2. The dye-sensitized solar cell according to claim 1, comprising:
two layers of an impervious material against the electrolyte (3) and capable to protect the cell (1) and (5), coated in its inner surface with a transparent and electrically conductive layer,
a photoelectrode (2),
an electrolyte (3),
a counter-electrode (4),
wherein said light reflective layer (6) is applied onto the outer surface of the counter-electrode (4).

3. The dye-sensitized solar cell according to claim 2, wherein said material of the two layers (1) and (5) is glass or polyethylene terephthalate (PET).

4. The dye-sensitized solar cell according to claim 2, wherein the photoelectrode (2) is dye-sensitized, nanoparticulated titanium dioxide.

5. The dye-sensitized solar cell according to claim 2, wherein the electrolyte (3) is a triiodide/iodide redox pair.

6. The dye-sensitized solar cell according to claim 2, wherein the counter-electrode (4) is a thin platinum layer with a thickness between 5 nm and 500 nm.

7-8. (canceled)

9. The dye-sensitized solar cell according to claim 2, wherein the counter-electrode (4) comprises nanostructured carbon particles which may be either doped, or not doped, with platinum particles.

10. The dye-sensitized solar cell according to claim 1, wherein said paint is white.

11. The dye-sensitized solar cell according to claim 2 wherein said paint is white.

12. The dye-sensitized solar cell according to claim 3, wherein said paint is white.

13. The dye-sensitized solar cell according to claim 4, wherein said paint is white.

14. The dye-sensitized solar cell according to claim wherein said paint is white.

15. The dye-sensitized solar cell according to claim 6, wherein said paint is white.

16. The dye-sensitized solar cell according to claim 9, wherein said paint is white.
